(19) United States
(12) Patent Application Publication
(10) Pub. No.: US 2024/0214742 A1
(43) Pub. Date: Jun. 27, 2024

(54) TRANSMISSION/RECEPTION ARRANGEMENT FOR TRANSMISSION/RECEPTION OF MAGNETIC SIGNALS

(71) Applicants: Fraunhofer-Gesellschaft zur Förderung der angewandten Forschung e.V., München (DE); Technische Hochschule Nürnberg Georg-Simon-Ohm, Nürnberg (DE)

(72) Inventors: Gerd KILIAN, Erlangen (DE); Johannes WORM, Erlangen (DE); Stefan ERETH, Erlangen (DE); Thomas LAUTERBACH, Nürnberg (DE); Tobias DRÄGER, Erlangen (DE)

(21) Appl. No.: 18/392,767

(22) Filed: Dec. 21, 2023

(30) Foreign Application Priority Data
Dec. 22, 2022 (DE) 10 2022 214 355.8

(51) Int. Cl. H04R 9/06; H04L 25/49; H04M 1/60

(52) U.S. Cl. CPC H04R 9/06; H04L 25/4902; H04M 1/6016; H03F 3/193

(57) ABSTRACT

Embodiments provide a transmission/reception arrangement for transmission/reception of magnetic signals, wherein the transmission/reception arrangement comprises a microcontroller and an electromagnetic resonant circuit, wherein the microcontroller is configured, in a transmission mode,
to operate the electromagnetic resonant circuit in series resonance, and
to generate a first signal for driving the electromagnetic resonant circuit, and to drive the electromagnetic resonant circuit with the generated first signal so as to generate, with the electromagnetic resonant circuit, a first magnetic signal carrying first data,
   wherein the microcontroller is configured, in a reception mode,
to operate the electromagnetic resonant circuit in parallel resonance, and
to evaluate a second signal provided by the electromagnetic resonant circuit, said second signal depending on a second magnetic signal detected by the electromagnetic resonant circuit, so as to receive second data.

### CROSS-REFERENCE TO RELATED APPLICATION

This application claims priority from German Patent Application No. DE 10 2022 214 355.8, which was filed on Dec. 22, 2022, and is incorporated herein in its entirety by reference.

Embodiments of the present invention concern a transmission/reception arrangement for transmission/reception of magnetic signals, and in particular, a transmission/reception arrangement that transmits and/or receives the magnetic signals by means of an electromagnetic resonant circuit. Some embodiments concern an apparatus for the transfer of data between two resonant circuits.

### BACKGROUND OF THE INVENTION

Nowadays, mobile phones are widespread. Loudspeakers are installed in mobile phones. These are (almost) exclusively so-called electromagnetic loudspeakers.

As described in [1], a unidirectional data connection (e.g. a configuration connection) from the mobile telephone to another device can be realized by means of an electromagnetic loudspeaker of a mobile phone.
[2] then describes how a bidirectional data connection between the mobile phone and another device can be realized by means of a modification/enhancement of a mobile phone, whereas [3] describes how a bidirectional data connection can be realized with a standard mobile phone, i.e. without modification/enhancement of the same.
[4] and [5] describe realizations of tunable bidirectional data connections between a mobile phone and another device.
[6] describes home applications of the systems described in [1] to [5].
[7] describes the coil required for communication without loudspeakers, a method for bidirectional communication with higher data rates and a connection to higher-level devices.

### SUMMARY

An embodiment may have a transmission/reception arrangement for transmission/reception of magnetic signals, wherein the transmission/reception arrangement comprises: a microcontroller, and an electromagnetic resonant circuit, wherein the microcontroller is connected to the electromagnetic resonant circuit, wherein the microcontroller is configured, in a transmission mode,
to operate the electromagnetic resonant circuit in series resonance, and
to generate a first signal for driving the electromagnetic resonant circuit, and to drive the electromagnetic resonant circuit with the generated first signal so as to generate, with the electromagnetic resonant circuit, a first magnetic signal carrying first data,
   wherein the microcontroller is configured, in a reception mode,
to operate electromagnetic resonant circuit in series resonance, and
to evaluate a second signal provided by the electromagnetic resonant circuit, said second signal depending on a second magnetic signal detected by the electromagnetic resonant circuit, so as to receive second data.

Another embodiment may have a device, comprising: a configuration interface and/or operation interface for configuring and/or operating the device, wherein the configuration interface and/or operation interface comprises a transmission/reception arrangement according to the invention.

Embodiments provide a transmission/reception arrangement (or array) for transmission/reception of magnetic signals. The transmission/reception arrangement comprises a microcontroller and an electromagnetic resonant circuit [e.g. with a coil and a capacitor], wherein the microcontroller is connected [e.g. directly] to the electromagnetic resonant circuit, wherein the microcontroller is configured, in a transmission mode,
to operate the electromagnetic resonant circuit in series resonance, and
to generate a first signal for driving the electromagnetic resonant circuit [e.g. operated in series resonance], and to drive the electromagnetic resonant circuit with the generated first signal so as to generate, with the electromagnetic resonant circuit, a first magnetic signal [e.g. a magnetic field] carrying first data,
   wherein the microcontroller is configured, in a reception mode,
to operate the [e.g. same] electromagnetic resonant circuit in parallel resonance, and
to evaluate a second signal provided by the electromagnetic resonant circuit [e.g. operated in parallel resonance], said second signal depending on a second magnetic signal [e.g. magnetic field] detected by the electromagnetic resonant circuit, so as to receive second data.

In embodiments, the electromagnetic resonant circuit comprises a coil and a capacitor connected in series between a first node and second node, wherein the coil and capacitor are connected via a third node.

In embodiments, the microcontroller is configured, in the transmission mode,
to apply the first signal at the first node, and
to apply a reference potential or a signal that is complementary to the first signal at the second node.

In embodiments, the microcontroller is configured, in the reception mode,
to apply a reference potential at the first node and the second node, and
to tap the second signal at the third node.

In embodiments, a first terminal [e.g. first pin] of the microcontroller is connected [e.g. directly or via an amplifier [e.g. MOSFET]] to the first node, wherein a second terminal [e.g. second pin] of the microcontroller is connected [e.g. directly] to the second node.

In embodiments, a third terminal [e.g. a third pin] of the microcontroller is connected [e.g. directly or via a comparator] to the third node.

In embodiments, the electromagnetic resonant circuit further comprises a tuning capacitor connected between the third node and a fourth terminal [e.g. fourth pin] of the microcontroller, wherein the microcontroller is configured to tune the electromagnetic resonant circuit by switching the fourth terminal to one of at least two different operation modes [e.g. in which a defined reference potential is provided and/or in which a signal that is complementary to the first signal is provided and/or in which a fourth terminal is switched to a high-impedance state (or high-ohmic state)].

In embodiments, the first signal is pulse-width modulated.

In embodiments, a frequency of the first magnetic signal and/or of the second magnetic signal is less than 50 kHz.

In embodiments, the electromagnetic resonant circuit further comprises a piezo element connected between the third node and a fifth terminal [e.g. fifth pin] of the microcontroller.

In embodiments, the electromagnetic resonant circuit further comprises a piezo element connected in parallel to the coil and/or the capacitor of the electromagnetic resonant circuit.

For example, the piezo element may be connected between the third node and a fifth terminal [e.g. fifth pin] of the microcontroller. For example, the microcontroller may be configured, in the transmission mode, to provide a reference potential at the fifth terminal, wherein the microcontroller is configured, in the reception mode, to switch the fifth terminal to a high-impedance state (or high-ohmic state).

In embodiments, the microcontroller is configured, in the transmission mode, to switch the fourth terminal to a high-impedance state, wherein the microcontroller is configured, in the reception mode, to provide a reference potential at the fourth terminal.

For example, a capacitance of the tuning capacitor may correspond to a capacitance of the piezo element with a tolerance of ±10%.

In embodiments, the electromagnetic resonant circuit comprises a further selectable tuning capacitor [e.g. connected between the third node and a sixth terminal [e.g. sixth pin] of the microcontroller], wherein the microcontroller is configured, in the transmission mode, to turn off the selectable tuning capacitor [e.g. switch the sixth terminal to a high-impedance state], wherein the microcontroller is configured, in the reception mode, to turn on the selectable tuning capacitor [e.g. provide a reference potential at the sixth terminal].

For example, a capacitance of the further tuning capacitor may correspond to a capacitance of the piezo element with a tolerance of ±10%.

In embodiments, the microcontroller is configured to tune, via the tuning capacitor, with an intended deviation [e.g. of ±5 to 15%, or ±2 to 25%], a resonance frequency of the electromagnetic resonant circuit to a resonance frequency of another electromagnetic resonant circuit magnetically coupled to the electromagnetic resonant circuit.

Further embodiments provide a transmission/reception arrangement for transmission/reception of magnetic signals. The transmission/reception arrangement comprises a microcontroller and an electromagnetic resonant circuit [e.g. with a coil and a capacitor], wherein the microcontroller is connected [e.g. directly] to the electromagnetic resonant circuit, wherein the microcontroller is configured, in a transmission mode,
to operate the electromagnetic resonant circuit in series resonance, and
to generate a first signal for driving the electromagnetic resonant circuit [e.g. operated in series resonance], and to drive the electromagnetic resonant circuit with the generated first signal so as to generate, with the electromagnetic resonant circuit, a first magnetic signal [e.g. magnetic field] carrying first data,
   wherein the microcontroller is configured, in a reception mode,
to operate the [e.g. same] electromagnetic resonant circuit in series resonance, and
to evaluate a second signal provided by the electromagnetic resonant circuit [e.g. operated in series resonance], said second signal depending on the second magnetic signal [e.g. magnetic field] detected by the electromagnetic resonant circuit, so as to receive second data.

In embodiments, the electromagnetic resonant circuit comprises a coil and a capacitor connected in series between a first node and a second node, wherein, in a transmission mode,
a first reference potential [e.g. ground] is applied at the second node [e.g. wherein the microcontroller is configured to apply the first reference potential at the node], and
the microcontroller is configured to generate a first signal for driving the electromagnetic resonant circuit, and to apply [e.g. in a high resistance manner] the generated first signal to the electromagnetic resonant circuit via the first node so as to generate, with the electromagnetic resonant circuit, a first magnetic signal [e.g. magnetic field] carrying first data,
   wherein, in a reception mode,
a second reference potential [e.g. ground] is applied at the first or second node [e.g. wherein the microcontroller is configured to apply the second reference potential at the node], and
to tap [e.g. in a high-impedance manner], via the first or second node, a second signal provided by the electromagnetic resonant circuit, said second signal depending on a second magnetic signal [e.g. magnetic field] received by the electromagnetic resonant circuit, so as to obtain second data.

Further embodiments provide a transmission/reception arrangement for transmission/reception of magnetic signals. The transmission/reception arrangement comprises a microcontroller and an electromagnetic resonant circuit [with a coil and a capacitor], wherein the microcontroller is connected [e.g. directly] to the electromagnetic resonant circuit, wherein the microcontroller is configured, in a transmission mode,
to operate the electromagnetic resonant circuit in series resonance, and
to generate a first signal for driving the electromagnetic resonant circuit [e.g. operated in series resonance], and to drive the electromagnetic resonant circuit with the generated first signal so as to generate, with the electromagnetic resonant circuit, a first magnetic signal [e.g. a magnetic field] carrying first data,
   wherein the microcontroller is configured, in a reception mode,
to operate the [e.g. same] electromagnetic resonant circuit in series resonance, and
evaluate a second signal provided by the electromagnetic resonant circuit [e.g. operated in series resonance], said second signal depending on a second magnetic signal [e.g. a magnetic field] detected by the electromagnetic resonant circuit, so as to receive second data.

In embodiments, the microcontroller is connected to the electromagnetic resonant circuit [e.g. to the first node] via a reconfiguration circuit, wherein the microcontroller is configured, in the transmission mode,
[e.g. to deactivate the reconfiguration circuit, and]
to generate a first signal for driving the electromagnetic resonant circuit, and to drive the electromagnetic resonant circuit with the generated first signal so as to generate, with the electromagnetic resonant circuit, a first magnetic signal [e.g. magnetic field] carrying first data,
   wherein the microcontroller is configured, in a reception mode,
[e.g. to activate the reconfiguration circuit], and
to sense, via the reconfiguration circuit, a second signal provided by the electromagnetic resonant circuit, said second signal depending on a second magnetic signal [e.g. magnetic field] received by the electromagnetic resonant circuit, so as to obtain second data,
   wherein the reconfiguration circuit is configured to convert a current into an [e.g. proportional] output voltage [e.g. corresponding to a strictly monotonous function].

In embodiments, high-impedance manner means less than twice or five times the resistance of the coil of the electromagnetic resonant circuit.

In embodiments, the reconfiguration circuit is a current-voltage converter or a low-impedance amplifier (or a low-ohmic amplifier).

In embodiments, the low-impedance amplifier is a transimpedance amplifier or an operational amplifier connected as a transimpedance amplifier.

In embodiments, the electromagnetic resonant circuit comprises a coil and a capacitor connected in series between a first node and a second node, wherein the coil and the capacitor are connected to each other via a third node.

In embodiments, the microcontroller is configured, in the transmission mode, to apply the first signal at the first node.

In embodiments, the microcontroller is configured, in the transmission mode, to apply a reference potential or a signal that is complementary to the first signal at the second node.

In embodiments, the microcontroller is configured, in the reception mode, to apply a reference potential at the second node.

In embodiments, a first terminal [e.g. first pin] of the microcontroller is connected to the first node, wherein a second terminal [e.g. second pin] of the microcontroller is connected to the first node via the operational amplifier connected as a transimpedance amplifier.

In embodiments, the second node is connected to a third terminal [e.g. third pin] of the microcontroller or to a reference potential terminal [e.g. ground terminal].

In embodiments, the electromagnetic resonant circuit further comprises a tuning capacitor connected between the third node and a fourth terminal [e.g. fourth pin] of the microcontroller, wherein the microcontroller is configured to tune the electromagnetic resonant circuit by switching the fourth terminal to one of at least two different operation modes [e.g. in which a defined reference potential is provided, in which a signal that is complementary to the first signal is provided, in which the fourth terminal is switched to a high-impedance state].

In embodiments, a first input of the operational amplifier may be connected to the first node.

In embodiments, a second input of the operational amplifier may be connected to a reference potential terminal [e.g. ground terminal] via a bypass capacitor.

In embodiments, an output of the operational amplifier may be connected to the second terminal of the microcontroller.

In embodiments, a first resistor may be connected in series between the first node and the second terminal of the microcontroller.

In embodiments, a first diode may be connected in the forward direction between the first node and the second terminal of the microcontroller.

In embodiments, a second diode may be connected in the reverse direction between the first node and the second terminal of the microcontroller.

In embodiments, a first supply terminal of the operational amplifier may be connected to a supply voltage terminal.

In embodiments, a second supply terminal of the operational amplifier may be connected to a reference potential terminal [e.g. ground terminal].

In embodiments, the first supply terminal may be connected to the reference potential terminal [e.g. ground terminal] via two resistors connected in series.

In embodiments, a node between the two resistors connected in series may be connected to the second input of the operational amplifier.

In embodiments, the second terminal of a microcontroller may be connected to a fifth terminal of the microcontroller via a fourth resistor.

In embodiments, the fifth terminal of the microcontroller may be connected to a reference potential terminal [e.g. ground terminal] via a second capacitor.

In embodiments, the operational amplifier is configured, in the reception mode, to control a voltage Uₒᵤₜₚᵤₜ provided at the output, on the basis of the following equation:

$$\\ {U}_{output} = - {I}_{L} \cdot R 1 + {U}_{input 2}$$

wherein I_{L} is the current flowing through the coil of the electromagnetic resonant circuit wherein R1 is the resistance of the first resistor, and wherein U_{input 2} is a voltage at the second input of the operational amplifier.

In embodiments, the second terminal and the fifth terminal of the microcontroller are comparator inputs.

In embodiments, the first terminal of the microcontroller is connected [e.g. directly] to the first node.

In embodiments, the first terminal of the microcontroller is connected to the first node via an amplifier circuit.

In embodiments, the amplifier circuit comprises a first electronic switch and a second electronic switch connected in series between a supply voltage terminal and a reference potential terminal, wherein an output terminal of the amplifier circuit between the first electronic switch and the second electronic switch is connected to the first node, wherein the microcontroller is configured, in the transmission mode, to apply, via the amplifier circuit, a pulse-width modulated first signal at the first node.

Further embodiments provide a device with a configuration interface and/or operation interface for configuring and/or operating the device, wherein the configuration interface and/or operation interface comprises a transmission/reception arrangement according to one of the embodiments described herein.

### BRIEF DESCRIPTION OF THE DRAWINGS

Embodiments of the present invention will be detailed subsequently referring to the appended drawings, in which:

FIG. 1 shows a schematic block circuit diagram of a system with a user terminal device and another device according to a first exemplary implementation;

FIG. 2a shows a schematic block circuit diagram of a system with a user terminal device and another device according to a second exemplary implementation;

FIG. 2b shows a schematic block circuit diagram of a system with a user terminal device and another device according to a third exemplary implementation;

FIG. 2c shows a schematic block circuit diagram of a system with a user terminal device and another device according to a fourth exemplary implementation;

FIG. 3 shows a schematic block circuit diagram of a system with a user terminal device and another device according to a fifth exemplary implementation;

FIG. 4 shows a schematic block circuit diagram of a transmission/reception arrangement for transmission/reception of magnetic signals according to an embodiment of the present invention;

FIG. 5 shows a schematic block circuit diagram of a transmission/reception arrangement for transmission/reception of magnetic signals according to a further embodiment of the present invention;

FIG. 6 shows a schematic block circuit diagram of a transmission/reception arrangement for transmission/reception of magnetic signals according to further embodiment of the present invention;

FIG. 7 shows transfer functions of different combinations of resonant circuits in a diagram;

FIG. 8 shows a schematic block circuit diagram of a transmission/reception arrangement for transmission/reception of magnetic signals according to a further embodiment of the present invention;

FIG. 9 shows a schematic block circuit diagram of a transmission/reception arrangement for transmission/reception of magnetic signals according to a further embodiment of the present invention; and

FIG. 10 shows a schematic block circuit diagram of an exemplary implementation of the transmission/reception arrangement shown in FIG. 9 according to an embodiment of the present invention.

### DETAILED DESCRIPTION OF THE INVENTION

In the subsequent description of the embodiments of the present invention, the same elements or elements having the same effect are provided with the same reference numerals in the drawings so that their description is interchangeable.

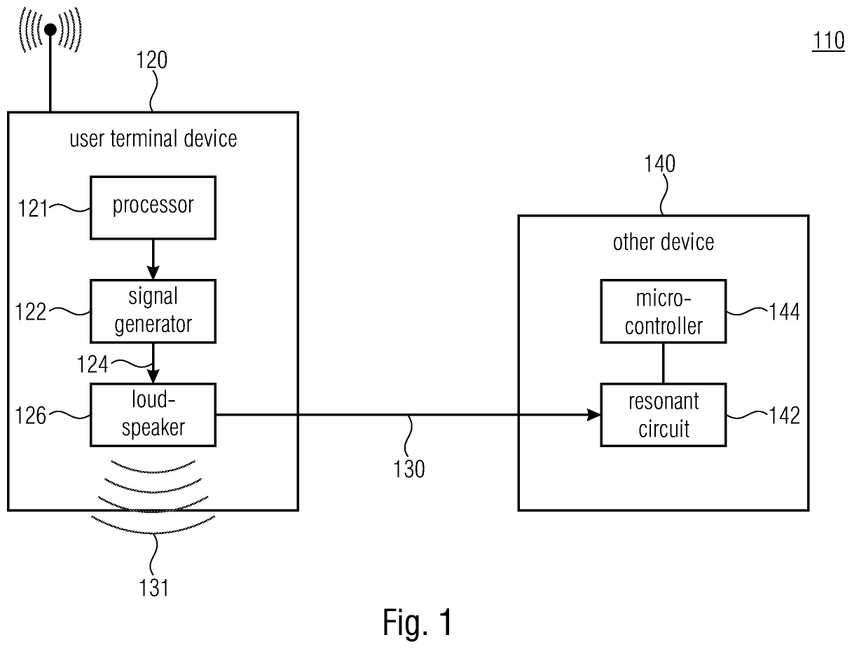

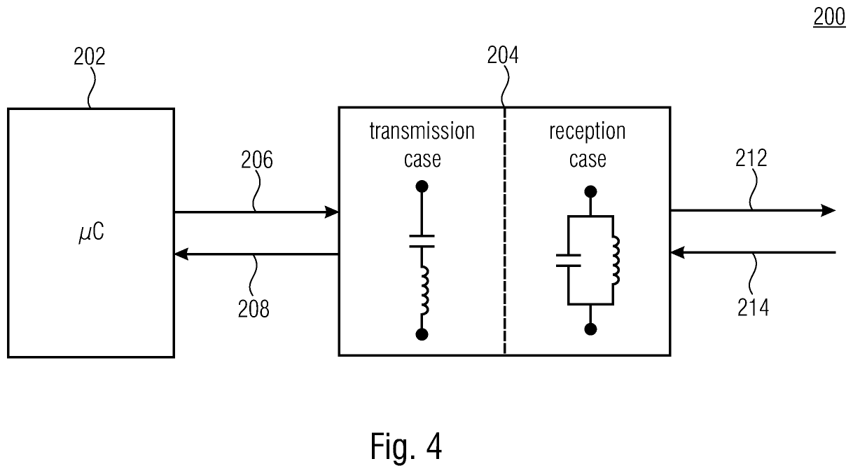

However, before describing embodiments of the present invention in more detail on the basis of FIGS. 4 to 10, an exemplary communication system in which the inventive transmission/reception arrangement may be used will first be described on the basis of FIGS. 1 to 3. However, embodiments are not limited to such applications, rather, the inventive transmission/reception arrangement can also be used in other communication systems, in particular when transferring data across short distances (e.g. up to one meter).

FIG. 1 shows a schematic block circuit diagram of a system 110 with a user terminal device 120 and another device 140 according to a first exemplary implementation.

The user terminal device 120 includes a processor 121, a signal generator 122, and a loudspeaker 126 with an electromagnetic actuator (e.g. an oscillation coil). The user terminal device 120 (or e.g. the processor 121 of the user terminal device 120) is configured to drive the signal generator 122, to generate a signal 124 for driving the loudspeaker 126, and to drive the loudspeaker 126 with the generated signal 124 so as to generate, via the loudspeaker 126 or the electromagnetic actuator of the loudspeaker 126, a magnetic signal/field 130 carrying data to be transferred from the user terminal device 120 to the other device 140.

The generated signal 124 may be in the ultrasound frequency range or above. The sound waves 131 also generated by driving the loudspeaker 126 with the generated signal 124 are therefore in a frequency range that humans cannot hear or can only barely hear or, due to the upper cutoff-frequency of the loudspeaker 126, are not radiated or only in an attenuated manner in the ideal case (e.g. no non-linearities).

For example, a frequency or a frequency range of the generated signal 126 may be above 16 kHz, e.g. in the range of between 16 kHz and 22 kHz.

The data may be modulated onto the generated signal 128, e.g. by means of FSK (FSK=Frequency Shift Keying), MSK (MSK=Minimum Shift Keying) or GMSK (GMSK=Gaussian Minimum Shift Keying). Obviously, any other modulation type may be used, such as ASK (ASK=Amplitude Shift Keying) or PSK (PSK=Phase Shift Keying) or OOK (OOK=On-Off Keying).

A ratio between the carrier frequency and the modulation bandwidth of the generated signal 124 may be less than 25% (or e.g. less than 20% or less than 15%).

The user terminal device 120 may be a mobile phone (smartphone) or a tablet.

As can be seen in FIG. 1, the other device 140 includes an electromagnetic resonant circuit 142 configured to detect the magnetic field 130 carrying the data. Furthermore, the other device 140 includes a microcontroller 144 configured to evaluate the detected magnetic field 130 so as to receive the data.

The data carried by the magnetic field 130 may be configuration data or operation data, for example. The microcontroller 144 may be configured to carry out an operational process on the basis of the operation data, or to configure the other device 140 on the basis of the configuration data, e.g. to embed the same into a wireless network.

For example, the other device 140 may be a user-configurable device, such as an IoT node (IoT=Internet of Things) (e.g. a sensor node or an actuator node) or a WLAN camera. In this case, the configuration data may comprise information for embedding the user-configurable device 140 into a wireless network (e.g. a sensor network or WLAN), such as a network name and a network key. Obviously, other parameters may be assigned to the user-configurable device 140 by the configuration data, such as a frequency channel to be used, time slots to be used, or a hopping pattern to be used.

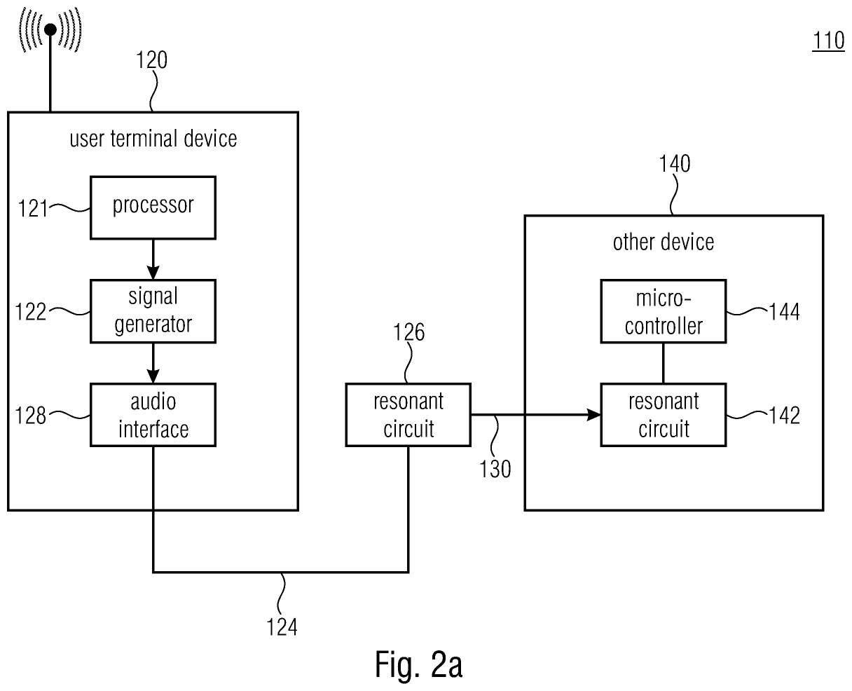

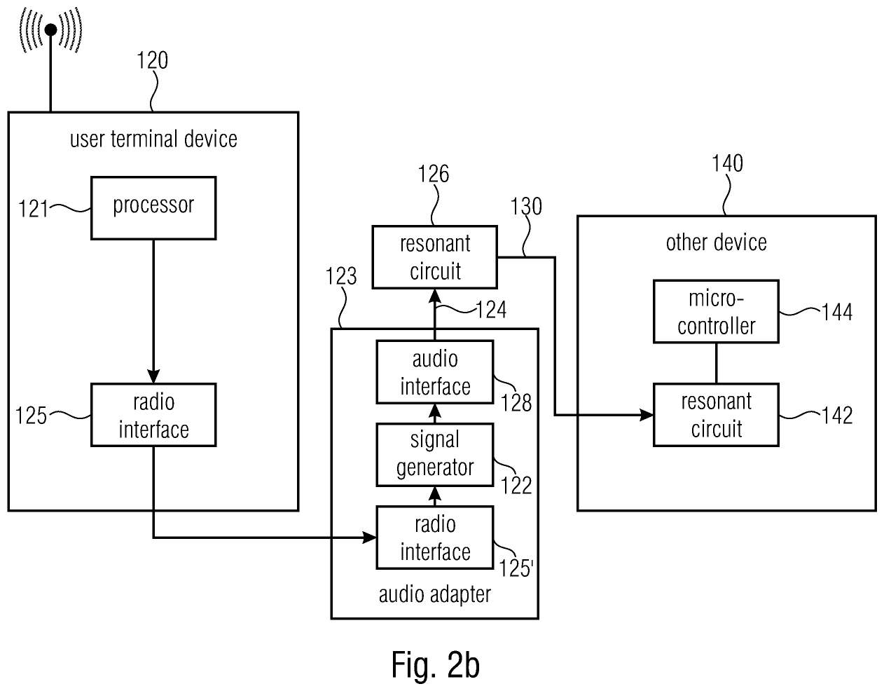

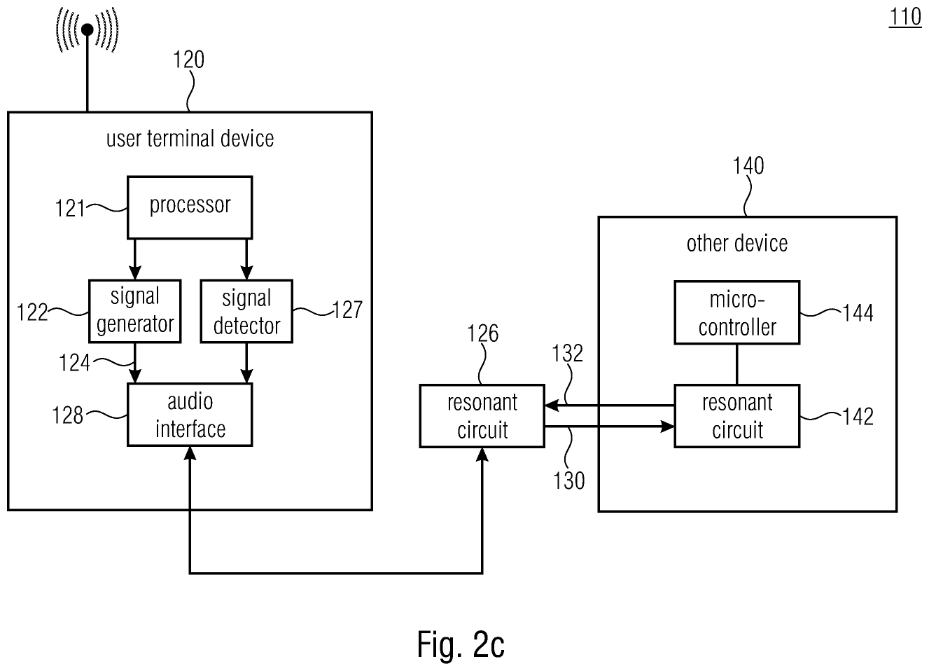

Instead of a loudspeaker, an electromagnetic resonant circuit connected to the user terminal device 120 may be used so as to generate the electromagnetic signal/field 130 carrying the first data, as will subsequently be described with reference to FIGS. 2a-2c.

FIG. 2a shows a schematic block circuit diagram of a system 110 with a user terminal device 120 and another device 140 according to a second exemplary implementation.

The user terminal device 120 includes a signal generator 122, wherein the user terminal device 120 (or e.g. a processor 121 of the user terminal device 120) is configured to drive the signal generator 122, to generate a signal 124 for driving an electromagnetic resonant circuit 126, and to drive the electromagnetic resonant circuit 126 with the generated signal 124 so as to generate, via the electromagnetic resonant circuit 126, a first magnetic field 130 carrying first data to be transferred from the user terminal device 120 to the other device 140.

The signal generator 122 may be an audio signal generator. Conventionally, such an audio signal generator 122 is configured to generate an audio signal for driving an audio reproduction device (e.g. headphones) connected to the user terminal device 120, wherein, according to FIG. 2a, instead of an audio reproduction device, the electromagnetic resonant circuit 126 is driven with the signal 124 generated by the audio signal generator 122 to generate the magnetic field 130 carrying the data. For example, the audio signal generator 122 may be an amplifier.

The electromagnetic resonant circuit 126 may be connected to the signal generator 122 via an audio interface 128. For example, the audio interface 128 may be a wired audio interface, such as a jack plug, a USB-C® audio connection or a Lightning® audio connection.

In the example shown in FIG. 2a, the user terminal device 120 comprises the signal generator 122. Alternatively, the signal generator 122 may also be configured outside of the user terminal device 120. For example, the signal generator 122 may be implemented in a wireless audio adapter connected to the user terminal device 120, as is shown in FIG. 2b.

In detail, FIG. 2b shows a schematic block circuit diagram of a system 110 with a user terminal device 120 and another device 140, wherein the user terminal device 120 is connected wirelessly to a wireless audio adapter 123 (e.g. via corresponding radio interfaces 125, 125′ (e.g. Bluetooth, WLAN, or certified wireless USB)) comprising the signal generator 122.

As can be seen in FIG. 2b, in this case, the electromagnetic resonant circuit 126 may be connected to the signal generator 122 via an audio interface 128 of the wireless audio adapter 123. The audio interface 128 may be a wired audio interface such as a jack plug, a USB-C® audio connection or a Lightning® audio connection.

For example, the wireless audio adapter 123 may be a Bluetooth, WLAN, or certified wireless USB audio adapter.

The arrangement shown in FIGS. 2a and 2b may also be used for bidirectional transmission of data between the user terminal device 120 and the other device 140, as will be subsequently described on the basis of FIG. 2c.

In detail, FIG. 2c shows a schematic block circuit diagram of a system 110 with a user terminal device 120 and another device 140 according to a fourth exemplary implementation.

The user terminal device 122 (or the processor 121 of the user terminal device 122) may be configured to generate, by means of the signal generator 122, a signal 124 for driving the electromagnetic resonant circuit 126 connected to the user terminal device 120, and to drive the electromagnetic resonant circuit 126 with the generated signal 124 so as to generate, via the electromagnetic resonant circuit 126, a first magnetic field 130 carrying first data to be transferred from the user terminal device 120 to the other device 140.

Furthermore, the user terminal device 122 (or the processor 121 of the user terminal device 122) may be configured to detect, by means of a signal detector 127, a signal provided by the electromagnetic resonant circuit 126 as a reaction to the second magnetic field 132 so as to detect second data to be transferred from the other device 140 to the user terminal device 120 and carried by the second magnetic field 130.

The user terminal device 122 may further be configured to evaluate the detected signal so as to receive the second data.

The user terminal device 122 may comprise the signal generator 122 as well as the signal detector 127. In this case, the electromagnetic resonant circuit 126 may be connected to the signal generator 122 and the signal detector 127 via the bidirectional audio interface 128 (e.g. audio output and audio input (microphone input)). For example, the bidirectional audio interface 128 may be a wired audio interface such as a jack plug, a USB-C® audio connection, or a Lightning® audio connection.

Obviously, analogously to FIG. 2b, it is also possible that the signal generator 122 and the signal detector 127 are configured to be outside of the user terminal device 120. Thus, the wireless audio adapter (cf. FIG. 2b) may comprise the signal generator 122 and the signal detector 127, wherein, in this case, the electromagnetic resonant circuit 126 is connected to the signal generator 122 and the signal detector 127 via the bidirectional audio interface of the wireless audio adapter. The bidirectional audio interface 128 may be a wired audio interface such as a jack plug, a USB-C® audio connection, or a Lightning® audio connection.

The microcontroller 144 of the other device 140 may be configured to generate, with the electromagnetic resonant circuit 142 of the other device 140, the second magnetic field 132 carrying the second data to be transferred from the other device 140 to the user terminal device 120.

For example, the microcontroller 144 of the other device 140 may be configured to generate a signal for driving the electromagnetic resonant circuit 142 of the other device 140, and to drive the electromagnetic resonant circuit 142 of the other device 140 with the generated signal so as to generate, via the electromagnetic resonant circuit 142 of the other device 140, the second magnetic field 132 carrying the second data.

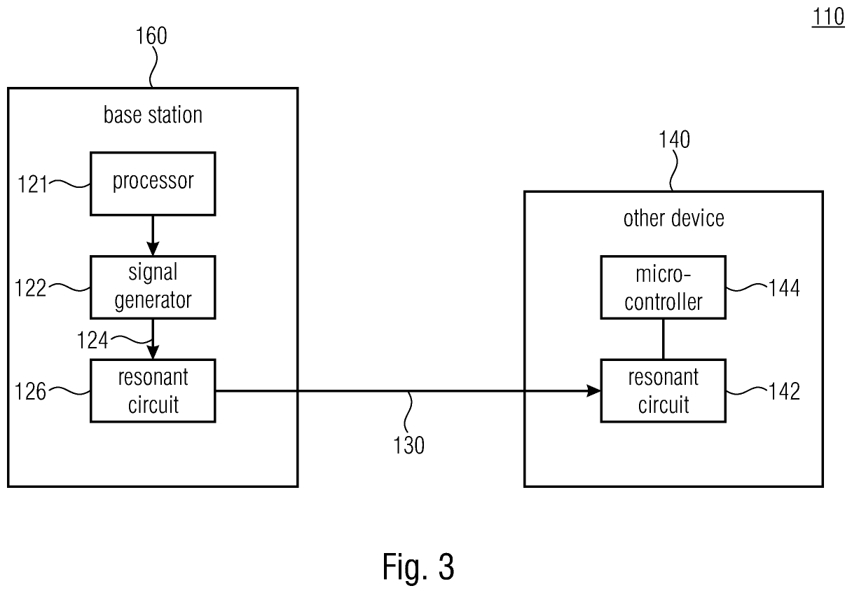

Obviously, it is also possible to integrate the electromagnetic resonant circuit 126 directly into the user terminal device, as is shown in FIG. 3.

In detail, FIG. 3 shows a schematic block circuit diagram of a system 110 with a user terminal device 120 and another device 140 according to a fifth exemplary implementation.

The user terminal device 122 includes a processor 121, a signal generator 122, and an electromagnetic resonant circuit 126. The user terminal device 122 (or the processor 121 of the user terminal device 122) may be configured to generate, by means of the signal generator 122, a signal 124 for driving the electromagnetic resonant circuit 126, and to drive the electromagnetic resonant circuit 126 with the generated signal 124 so as to generate, via the electromagnetic resonant circuit 126, a first magnetic field 130 carrying first data to be transferred from the user terminal device 120 to the other device 140.

Obviously, the example shown in FIG. 3 may also be extended by a bidirectional communication interface. To this end, e.g., the signal detector 127 known from FIG. 2c may be connected between the processor 121 and the electromagnetic resonant circuit, e.g. so as to detect a signal provided by the electromagnetic resonant circuit 126 as a reaction to the second magnetic field, in order to receive second data to be transferred from the other device 140 to the user terminal device 120 and carried by the second magnetic field.

As described in the following, the range and/or data rate in the communication system shown in FIGS. 1 to 3 is limited.

The transmission/reception arrangement with a microcontroller and an electromagnetic resonant circuit according to embodiments of the present invention described in the following enables increasing the range and/or data rate by an optimized interconnection of the electromagnetic resonant circuit.

In this case, the transmission/reception arrangement may be used in the above-described communication system, e.g. in the other device 140, but also in the user terminal device 120, e.g. as a replacement of a conventional RFID interface. Obviously, the transmission/reception arrangement can also be used in other communication systems, such as for requesting status and/or error information of the devices.

### 1. Configuration of a Resonant Circuit in Series Resonance for Transmission of Data and in Parallel Resonance for Reception of Data

In the communication system shown in FIGS. 1 to 3, an electromagnetic resonant circuit is used for generating the electromagnetic signal. This resonant circuit typically consists of a coil (inductance) and a capacitor (capacitance) that both operate for transmission and reception of data in parallel resonance. When transmitting by means of parallel resonance, the current flowing through the coil is limited by the voltage applied and therefore by the output voltage of the signal-generating component. The current flowing through the coil defines the strength of the magnetic field generated and therefore also the range of the communication system.

Embodiments of the present invention therefore provide a transmission/reception arrangement that uses a serial resonant circuit for transmission and a parallel resonant circuit for reception. By using a serial resonant circuit for transmission, the voltage applied at the coil is increased through the output voltage of the signal-generating component. This increases the current flowing through the coil, the strength of the magnetic field and ultimately the range of the communication system.

FIG. 4 shows a schematic block circuit diagram of a transmission/reception arrangement 200 for transmission/reception of magnetic signals according to an embodiment of the present invention.

The transmission/reception arrangement 200 includes a microcontroller 202 and an electromagnetic resonant circuit 204, e.g. with a coil and a capacitor, as indicated in FIG. 4, wherein the microcontroller 202 is connected to the electromagnetic resonant circuit 204.

The microcontroller 202 is configured, in a transmission mode,
to operate the electromagnetic resonant circuit 204 in series resonance, and
to generate a first signal 206 for driving the electromagnetic resonant circuit 204, and to drive the electromagnetic resonant circuit 204 with the generated first signal 206 so as to generate, with the electromagnetic resonant circuit 204, a first magnetic signal 212 carrying first data.

Furthermore, the microcontroller 202 is configured, in a reception mode,
to operate electromagnetic resonant circuit 204 in parallel resonance, and
to evaluate a second signal 208 provided by the electromagnetic resonant circuit 204, said second signal depending on a second magnetic signal 214 detected by the electromagnetic resonant circuit 204, so as to receive second data.

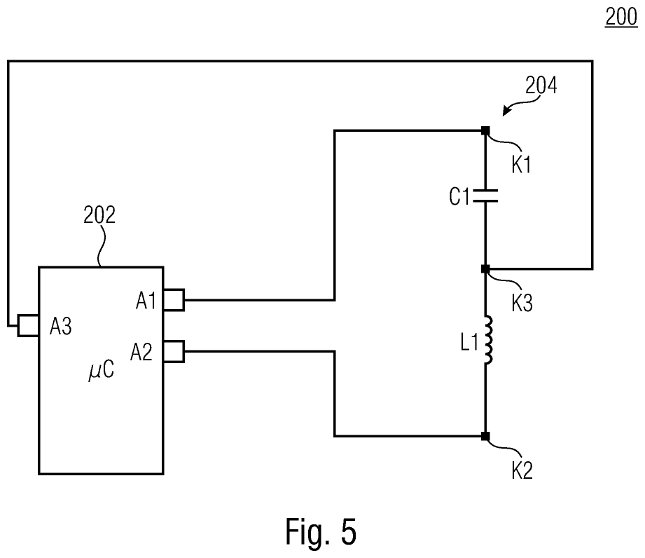

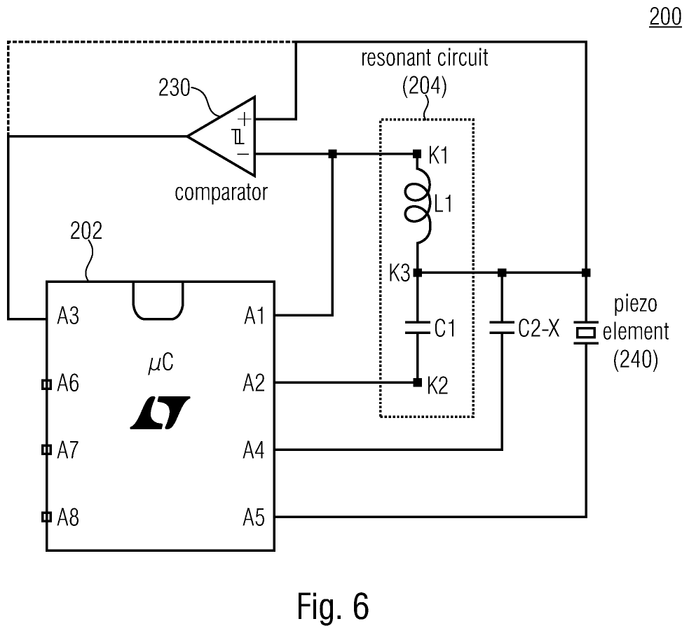

Detailed embodiments of the transmission/reception arrangement 200 shown in FIG. 4 are subsequently described on the basis of FIGS. 5 and 6 in more detail.

FIG. 5 shows a schematic block circuit diagram of a transmission/reception arrangement 200 for transmission/reception of magnetic signals according to a further embodiment of the present invention.

As can be seen in FIG. 5, the electromagnetic resonant circuit 204 may comprise a coil L1 and a capacitor C1 connected in series between a first node K1 and a second node K2, wherein the coil L1 and the capacitor C1 are connected to each other via a third node K3.

The embodiment shown in FIG. 5 exemplarily assumes that the capacitor C1 is connected between the first node K1 and the third node K3, whereas the coil L1 is connected between the third node K3 and the second node K2. However, in embodiments, the capacitor C1 and the coil L1 may also be connected in series between the first node K1 and the second node K2 the other way around, i.e. the coil L1 may be connected between the first node K1 and the third node K3, while the capacitor C1 is connected between the third node K3 and the second node K2 (cf. FIG. 6).

In embodiments, the microcontroller 202 may be configured, in the transmission mode,
to apply the first signal (e.g. transmission signal) at the first node K1, and
to apply a reference potential or a signal that is complementary to the first signal at the second node K2.

In embodiments, the microcontroller 202 may be configured, in the reception mode,
to apply a reference potential at the first node K1 and the second node K2, and
to tap the second signal (e.g. reception signal) at the third node K3.

In embodiments, to this end, a first terminal A1 of the microcontroller 202 may be connected directly to the first node K1, as exemplarily shown in FIG. 5. Obviously, the first terminal A1 of the microcontroller 202 may also connected to the first node K1 via a passive or active component (e.g. a resistor, capacitor, amplifier, comparator, etc.).

In embodiments, a second terminal A2 of the microcontroller 202 may be connected directly to the second node K2, as exemplarily shown in FIG. 5. Obviously, the second terminal A2 of the microcontroller 202 may also be connected to the second node K2 via a passive or active component (e.g. amplifier, comparator, etc.).

In embodiments, a third terminal A3 of the microcontroller 202 may be connected directly to the third node K3, as exemplarily shown in FIG. 5. Obviously, the third terminal A3 of the microcontroller 202 may also be connected to the third node K3 via a passive or active component (e.g. amplifier, comparator, etc.).

FIG. 6 shows a schematic block circuit diagram of a transmission/reception arrangement 200 for transmission/reception of magnetic signals according to a further embodiment of the present invention. In other words, FIG. 6 shows a circuitry implementation of a transmission/reception arrangement 200 operating the resonant circuit 204 as a series resonant circuit for transmission of data and as a parallel resonant circuit for reception of data.

The transmission/reception arrangement 200 includes the microcontroller 202 and the electromagnetic resonant circuit 204 with a coil L1 and a capacitor C1 connected between a first node K1 and a second node K2. FIG. 6 exemplarily assumes that the coil L1 is connected between a first node K1 and a third node K3, while the capacitor C1 is connected between the third node and the second node. However, the coil L1 and the capacitor C1 may also be interchanged, as described above.

A first terminal A1 of the microcontroller 202 may be connected to the first node K1 of the microcontroller 202, while a second terminal A2 of the microcontroller 202 may be connected to the second node K2. Alternatively, the second node K2 may also be switched to a reference potential, such as ground, or switched to the reference potential by the microcontroller 202, e.g. via a controllable switch. A third terminal A3 of the microcontroller 202 may be connected directly (cf. dotted line in FIG. 6) to a third node K3 of the electromagnetic resonant circuit 204 or via an active component 320 (e.g. a comparator).

In the transmission mode, the microcontroller 202 may be configured to apply the transmission signal (or first signal) at the first node K1. If the second node K2 of the resonant circuit 204 is connected to the second terminal A2 of the microcontroller 202, the microcontroller 202 may apply, in the transmission mode, a reference potential or a signal that is complementary to the transmission signal at the second mode K2.

In the reception mode, the microcontroller 202 may apply a reference potential at the first node K1 of the resonant circuit 204 and tap a reception signal (or second signal) at the third node K3 of the resonant circuit 204. If the second node K2 of the resonant circuit 204 is connected to the second terminal A2 of the microcontroller 202, the microcontroller 202 may apply a reference potential at the second node K2 in the reception mode.

As mentioned above, the third terminal A3 of the microcontroller 202 may be connected to the third node K3 of the resonant circuit 204 via an active component 230. The active component 230 may be an amplifier or a comparator, as exemplarily indicated in FIG. 6. In this case, a first input of the comparator may be connected to the third node K3 of the resonant circuit 204, while a second input of the comparator may be connected to the first node K1 of the resonant circuit. The second input of the comparator may also be switched to a reference potential or another fixed potential. The output of the comparator may be connected to the third terminal A3 of the microcontroller.

As can be seen in FIG. 6, the electromagnetic resonant circuit 204 may optionally comprise a tuning capacitor C2-X connected between the third node K3 and a fourth terminal A4 of the microcontroller 202. In this case, the microcontroller 202 may be configured to tune the electromagnetic resonant circuit 204 by switching the fourth terminal A4 to one of at least two different operation modes. For tuning the electromagnetic resonant circuit 204, for example, the microcontroller 202 may switch the fourth terminal to a defined reference potential, or may provide a signal that is complementary to the first signal (transmission signal) at the fourth terminal A4, or switch the fourth terminal A4 to a high-impedance state.

In embodiments, the microcontroller 202 (μC) may be configured so that, in the transmission case, it provides a pulse width modulation (PWM) at the first terminal A1 (or pin A1), while the second terminal A2 (pin A2) is pulled to a fixed reference potential, or, in case the microcontroller 202 may generate a differential PWM, it forms the complimentary output of the PWM output at the first terminal A1. The resonant circuit 204 operates in series resonance. In embodiments, additionally, the PWM signal between the first terminal A1 and the resonant circuit 204 may be amplified (e.g. by means of an amplifier or CMOS inverter) so as to decrease the source impedance.

In the reception case, the microcontroller 202 may pull the first terminal A1 and the second terminal A2 to a fixed reference potential, as a result of which the resonant circuit operates in parallel resonance. The voltage at the node between L1 and C1 (=third node K3) now oscillates around the reference potential provided by the first terminal A1 and may be led, e.g. via a comparator 230, to the third terminal A3 of the microcontroller 202, which reads the data received. If the third terminal A3 is a comparator input of the microcontroller 202, the voltage between L1 and C1 may also be led directly to the third terminal A3.

In embodiments, the fourth terminal A4 (pin A4) may combine all terminals (or pins) that are connected to a tuning capacitor C2-X. Through the same, in the reception case, by providing a fixed reference potential, the capacitance of the resonant circuit 204 may be increased, or it may be decreased by a configuration as a high-impedance input, so as to influence the resonance frequency of the resonant circuit 204. This takes place in the same way in the transmission case, however, if the microcontroller 202 operates with a differential PWM, the fourth terminal A4 as a complimentary output of the PWM in addition to the second terminal A2, for increasing the capacitance.

In embodiments, the same resonant circuit 204 may be used both for reception of data as well as for transmission of data.

In embodiments, the signal-generating component (e.g. microcontroller 202) may drive the resonant circuit 204 as a series resonant circuit for transmission of data.

In embodiments, the signal-generating component (e.g. microcontroller 202) may configure the resonant circuit 204 as a parallel resonant circuit for reception of data.

In embodiments, the signal-generating component (e.g. microcontroller 202) may vary the capacitance of the resonant circuit 204 so as to change the resonance frequency of the same.

By using a resonant circuit in parallel and series resonances, embodiments enable increasing the range of the communication system while additionally still allowing the reception of data.

In embodiments, the microcontroller 202 may drive the resonant circuit 204 with a PWM (or a PWM modulated signal).

In embodiments, the comparator 230 may be implemented in the microcontroller 202 but also outside of the microcontroller 202.

In embodiments, the microcontroller 202 may directly drive the resonant circuit 204.

Alternatively, in embodiments, the control signal (or transmission signal) may be amplified with an amplifier stage (e.g. CMOS inverter, operational amplifier).

### 2. Parallel Connection of a Piezo Element to the Tuning Capacitors to Enable Bidirectional Communication Via Audio

In embodiments, bidirectional communication via audio may be realized. As can be seen in FIG. 6, to this end, optionally, a piezo element 240 in parallel to the capacitor C1 (e.g. and the capacitor C2-X) may be connected to the coil L1 (or the third node K3) and the fifth terminal A5 (e.g. PIN A5) of the microcontroller 202. Now, if transmission is intended via the piezo element 240, the microcontroller 202 may provide a fixed reference potential via the fifth terminal A5. Due to the self-capacitance of the piezo element 240, however, the resonance frequency of the resonant circuit changes. This may be compensated by removing capacitors of the same capacitance as the piezo element 240 from the resonant circuit by placing the pins of the microcontroller they are connected to into a high-impedance state. In the reception case, the microcontroller 202 may place the fifth terminal A5 into a high-impedance state, as are result of which the piezo element 240 is removed from the resonant circuit, corresponding capacitors are connected, and the reception of data is carried out via the coil L1 as described in section 1. This has the advantage that any existing acoustic sources of interference are masked out.

In embodiments, as a tuning capacitor (for compensating the piezo element 240), the tuning capacitor C2-X or another (additional) tuning capacitor may be used, e.g., connected between the third node K3 and a terminal (e.g. terminal A6) of the microcontroller 202.

In embodiments, in addition to the method described in section 2, the piezo element 240 may also be driven directly. To this end, a terminal, or pin, of the microcontroller 202 (e.g. the first terminal A1 in the case without an external comparator) connected directly to the piezo element may be switched to a fixed potential. For example, the excitation may be carried out by the fifth terminal A5. The advantage of this is that electromagnetic interference coupling into the coil L1 does not affect the transmission behavior.

In embodiments, the same communication system, or the same means for transmission/reception, allows transmission via audio as well as via magnetic fields.

In embodiments, bidirectional communication with a conventional, or unmodified, user terminal device (e.g. mobile phone) may be enabled by the integration of a piezo element into the transmission/reception arrangement.

In embodiments, reception of data in bidirectional communication with a mobile phone is not influenced by acoustic interference sources.

In embodiments, the electromagnetic resonant circuit with the coil L1 and the piezo element (and the capacitor C1) is tunable.

In embodiments, the piezo element is part of a tuned resonant circuit.

In embodiments, voltage overshoot in the resonant circuit leads to a better control of the piezo element.

In embodiments, the piezo element may also be driven directly without a resonant circuit.

In embodiments, in the transmission case, there is no influence by means of magnetic interference.

### 3. Unsymmetrical Tuning of Two Resonant Circuits

[3] describes a possibility to increase the data rate of a communication system by also using frequencies outside of the resonance of the resonant circuit for transmission of data.

However, this has the disadvantage that the range decreases significantly outside of the resonance frequency. A further possibility to increase the bandwidth and therefore the data rate is to ohmically attenuate the resonant circuit (i.e. in a low-impedance manner); however, this also decreases the range significantly.

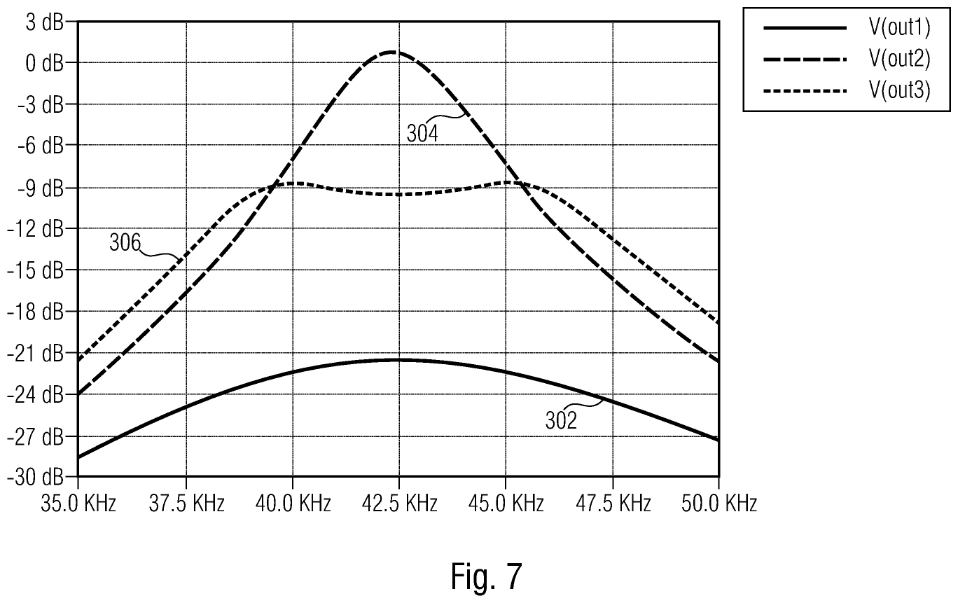

Embodiments provide a possibility to increase the bandwidth without heavily influencing the range. In embodiments, the two resonant circuits communicating with each other are not tuned to the same frequency as previously, but are tuned to two frequencies slightly deviating from each other, as will be described in the following on the basis of FIG. 7. In detail, FIG. 7 shows transfer functions of different combinations of resonant circuits in a diagram. Here, the ordinate describes the attenuation in dB and the abscissa describes the frequency in kHz. For better comparability, all three examples in FIG. 7 are operated with the same ideal voltage source. The results are shown in comparison to the input voltage (dB).

In FIG. 7, a third curve 306 V (out3) shows an exemplary transfer function between two resonant circuits that are tuned to two frequencies that slightly deviate from each other, according to embodiments. In detail, specifically, the resonant circuit of the first device is tuned to the upper modulation frequency of 45 kHz, and the resonant circuit of the second device is tuned to the lower modulation frequency of 40 kHz.

In contrast, the second curve 304 V (out2) shows a transfer function between two devices in which the resonant circuits are tuned to the carrier frequency of 42.5 kHz. While the absolute signal amplitude is higher, the bandwidth is too low to enable communication with a high date rate.

On the other hand, the first curve 302 V (out1) describes a transfer function between two devices in which the resonant circuits are tuned to one frequency, wherein the resonant circuits are ohmically attenuated so as to reach the same bandwidth as in the third curve 306 V (out3). It can be clearly seen that a small signal amplitude is achieved.

For example, in combination with the tunability of the communication system, or the transmission/reception arrangement, of section 1, this makes it possible to develop a system that, when establishing a connection, performs the communication with identically tuned resonant circuits, after both sides know about the capabilities of the respectively other participant and the link budget is sufficient, the two resonant circuits are tuned to different frequencies and there may be a switch to a higher data rate.

In embodiments, the two systems (or resonant circuits) communicating with each other may be tuned to two different frequencies.

Embodiments enable a higher data rate/bandwidth by tuning to two different frequencies.

In embodiments, the range is better than in the case of two resonant circuits that are tuned to the same frequencies but are ohmically attenuated for increasing the data rate.

In embodiments, the two communication partners autonomously detect the frequency they have to tune to by one communication partner varying the transmission data rate and the other varying the tuning of its resonant circuit.

### 4. Transmission and Reception with a Series Resonant Circuit

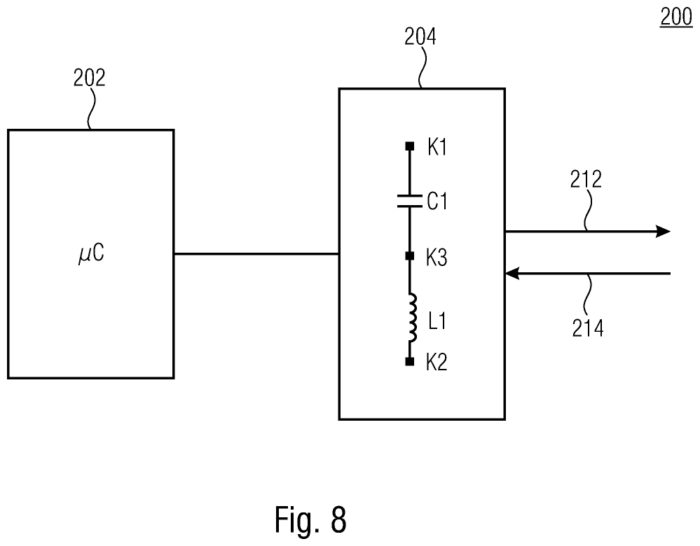

FIG. 8 shows a schematic block circuit diagram of a transmission/reception arrangement 200 for transmission/reception of magnetic signals according to a further embodiment of the present invention.

The transmission/reception arrangement 200 includes a microcontroller 202 and an electromagnetic resonant circuit 204, wherein the microcontroller 202 is connected to the electromagnetic resonant circuit 204. The electromagnetic resonant circuit 204 may comprise a coil L1 and a capacitor C1 connected in series between a first node K1 and a second node K2, wherein the coil L1 and the capacitor C1 are connected via a third node K3.

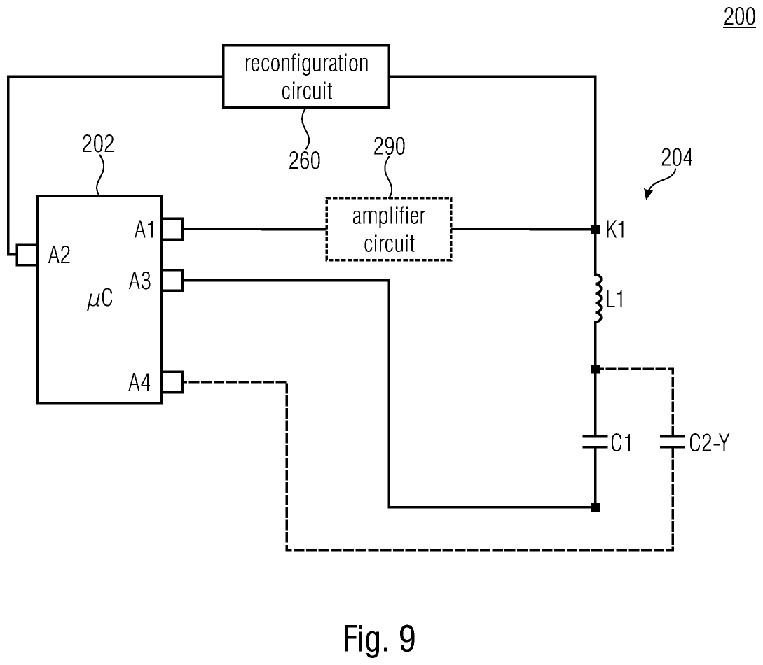

The embodiment shown in FIG. 8 exemplarily assumes that the capacitor C1 is connected between the first node K1 and third node K3, while the coil L1 is connected between the third node K3 and the second node K2. However, in embodiments, the capacitor C1 and the coil L1 may also be connected the other way round, in series between the first node K1 and the second node K2, i.e. the coil L1 may be connected between the first node K1 and the third node K3, while the capacitor C1 may be connected between the third node K3 and the second node K2 (cf. FIG. 9).

In the transmission mode, a first reference potential (e.g. ground) is applied at the second node K2, wherein the microcontroller 202 is configured to generate a first signal for driving the electromagnetic resonant circuit 204, and to apply the generated first signal via the first node K1 to the electromagnetic resonant circuit (e.g. in a low-impedance state) so as to generate, with the electromagnetic resonant circuit 204, a first magnetic signal 212 (e.g. magnetic field) carrying first data. For example, to this end, the first node K1 may be connected to a terminal (e.g. first terminal A1) of the microcontroller.

For example, to this end, the second node K2 may be connected to a terminal (e.g. third terminal) of the microcontroller 202, wherein the microcontroller 202 is configured to switch this terminal to the first reference potential, or to provide the first reference potential at this terminal. Alternatively, the second node K2 may also be switched to the first reference potential (e.g. ground), or may be switched to the reference potential by the microcontroller 202, e.g. via a controllable switch.

In the reception case, a second reference potential (e.g. ground) is applied to one of the first node K1 and the second node K2, wherein the microcontroller 202 is configured to tap (e.g. in a low-impedance manner), via the other one of the first node K1 and the second node K2, a second signal provided by the electromagnetic resonant circuit 204, said second signal depending on a second magnetic signal 214 (e.g. magnetic field) received by the electromagnetic resonant circuit 204, so as to obtain second data.

For example, to this end, one of the first node K1 and the second node K2 may be connected to a terminal (e.g. third terminal) of the microcontroller 202, wherein the microcontroller 202 is configured to switch this terminal to the second reference potential, or to provide the second reference potential at this terminal. Alternatively, this node may also be switched to the second reference potential (e.g. ground), or may be switched to the reference potential by the microcontroller 202, e.g. via a controllable switch.

For example, to this end, the other of the first node K1 and the second node K2 may be connected to a further terminal (e.g. second terminal) of the microcontroller 202, e.g., directly or via an active or passive component or via a circuit.

In embodiments, low-impedance means less than twice or five times the resistance of the coil of the electromagnetic resonant circuit.

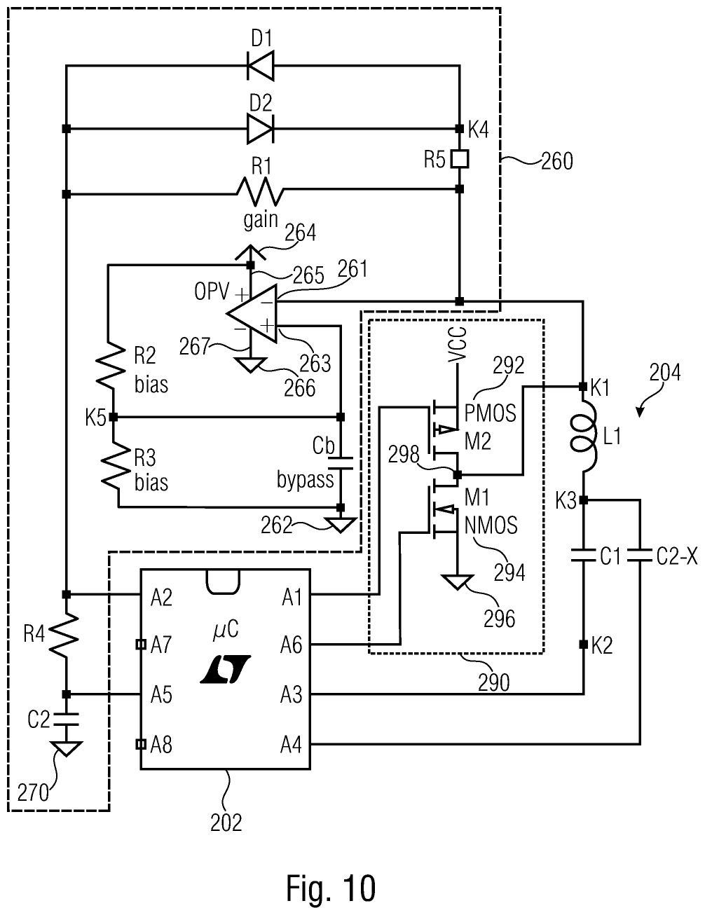

Detailed embodiments of the transmission/reception arrangement 200 shown in FIG. 8 are subsequently described in more detail on the basis of FIGS. 9 and 10.

FIG. 9 shows a schematic block circuit diagram of a transmission/reception arrangement 200 for transmission/reception of magnetic signals according to a further embodiment of the present invention.

The transmission/reception arrangement 200 includes the microcontroller 202 and the electromagnetic resonant circuit 204 with a coil L1 and a capacitor C1 connected between a first node K1 and a second node K2. FIG. 9 exemplarily assumes that the coil L1 is connected between a first node K1 and a third node K3, while the capacitor C1 is connected between the third node and the second node. The coil L1 and the capacitor C1 may also be interchanged, as described above.

A first terminal A1 of the microcontroller 202 may be connected to the first node K1 of the resonant circuit 204, e.g., directly or via an optional amplifier circuit 290, as indicated in FIG. 9.

A second terminal A2 of the microcontroller 202 may be connected to the first node K1 of the resonant circuit via a reconfiguration circuit 260. In this case, the reconfiguration circuit 260 is configured to convert a current into a proportional output voltage.

A third terminal A3 of the microcontroller 202 may be connected to the second mode K2 of the resonant circuit. Alternatively, the second node K2 may also be switched to a reference potential, such as ground, or may be switched to the reference potential by the microcontroller 202, e.g., via a controllable switch.

In this case, the microcontroller 202 is configured to, in a transmission mode,
deactivate or continue to run the reconfiguration circuit 260, for example, and
to generate a first signal for driving the electromagnetic resonant circuit 204, and to drive the electromagnetic resonant circuit 204 with the generated first signal so as to generate, with the electromagnetic resonant circuit 204, a first magnetic signal carrying first data,

Furthermore, the microcontroller 202 is configured, in a reception mode,
to activate or continue to run the reconfiguration circuit 260, for example, and
to sense, via the reconfiguration circuit 260, a second signal provided by the electromagnetic resonant circuit 204, said second signal depending on a second magnetic signal (e.g. magnetic field) received by the electromagnetic resonant circuit 204, so as to obtain second data.

In embodiments, the reconfiguration circuit 260 may be a current-voltage transducer or a low-impedance amplifier. For example, the low-impedance amplifier may be a transimpedance amplifier or an operational amplifier connected as a transimpedance amplifier.

As can be seen in FIG. 9, the electromagnetic resonant circuit 204 may optionally comprise a tuning capacitor C2X connected between the third node K3 and a fourth terminal A4 of the microcontroller 202. In this case, the microcontroller 202 may be configured to tune the electromagnetic resonant circuit 204 by switching the fourth terminal A4 to one of at least two different operation modes. For example, for tuning the electromagnetic resonant circuit 204, the microcontroller 202 may switch the fourth terminal A4 to a defined reference potential, or may provide a signal that is complimentary to the first signal (transmission signal) at the fourth terminal A4, or switch the fourth terminal A4 to a high-impedance state.

Embodiments of the reconfiguration circuit 260 and the amplifier circuit 290 are subsequently described on the basis of FIG. 10.

In detail, FIG. 10 shows a schematic block circuit diagram of an exemplary implementation of the transmission/reception arrangement shown in FIG. 9, according to an embodiment of the present invention.

As can be seen in FIG. 10, the reconfiguration circuit 260 may be an operational amplifier connected as a transimpedance amplifier that may be connected as described in the following.

In embodiments, a first input 261 of the operational amplifier OPV may be connected to the first node K1.

In embodiments, a second input 263 of the operational amplifier OPV may be connected to a reference potential terminal 262 (e.g. ground terminal) via a bypass capacitor CB.

In embodiments, an output of the operational amplifier OPV may be connected to the second terminal A2 of the microcontroller 202.

In embodiments, a first resistor R1 may be connected in series between the first node K1 and the second terminal A2 of the microcontroller 202.

In embodiments, a first diode D1 may be connected in the forward direction between the first node K1 and the second terminal A2 of the microcontroller 202.

In embodiments, a second diode D2 may be connected in the reverse direction between the first node K1 and the second terminal A2 of the microcontroller 202.

In embodiments, a fifth resistor R5 may be connected in series between a fourth node K4 and the first node K1, wherein the first diode D1 and the second diode D5 are connected to the first node K1 via the fifth resistor R5. Here, a resistance of the fifth resistor R5 may be smaller than a resistance of the first resistor R1.

In embodiments, a first supply terminal 265 of the operational amplifier OPV may be connected to a supply voltage terminal 264.

In embodiments, a second supply terminal 267 of the operational amplifier OPV may be connected to a reference potential terminal 266 (e.g. ground terminal).

In embodiments, the first supply terminal 264 may be connected to the reference potential terminal 262 (e.g. ground terminal) via two resistors R2 and R3 connected in series.

In embodiments, a node K5 between the two resistors R2 and R3 connected in series may be connected to the second input 263 of the operational amplifier OPV.

In embodiments, the second terminal A2 of the microcontroller 202 may be connected to a fifth terminal A5 of the microcontroller via a fourth resistor R4.

In embodiments, the fifth terminal A5 of the microcontroller 202 may be connected to a reference potential terminal 270 (e.g. ground terminal) via a second capacitor C2.

As can be further seen in FIG. 10, in embodiments, the amplifier circuit 290 may comprise a first electronic switch 292 and a second electronic switch 294 connected in series between a supply voltage terminal VCC and a reference potential terminal 269, wherein an output terminal 298 of the amplifier circuit 290 is connected to the first node K1 between the first electronic switch 292 and the second electronic switch 294. In embodiments, the electronic switches may be bipolar transistors or field-effect transistors, such as PMOS (p-channel MOSFET) and NMOS (n-channel MOSFET), as exemplary shown in FIG. 10.

In embodiments, the microcontroller 202 may be configured, in the transmission mode, to apply a pulse-width modulated first signal to the first node K1 via the amplifier circuit 290. To this end, for example, a first terminal A1 of the microcontroller 202 may be connected to a control terminal (e.g. base or gate) of the first electronic switch 292, while a sixth terminal A6 of the microcontroller 202 may be connected to a control terminal (e.g. base or gate) of the second electronic switch 294, for example.

In embodiments, the first electronic switch 292 and the second electronic switch 294 may be connected such that the first electronic switch 292 and the second electronic switch 294 have a high impedance. For example, in the case of a PMOS and an NMOS, as shown in FIG. 10, the microcontroller 202 may provide a low voltage at the sixth terminal for the NMOS and a high voltage at the first terminal A1 for the PMOS.

Thus, in embodiments, the circuit shown in FIG. 6 may be used for transmission from a series resonant circuit to a series resonant circuit. To this end, as shown in FIG. 10, the comparator of FIG. 6 may be replaced by the reconfiguration circuit 290 (e.g. an operational amplifier (OPV) connected as a transimpedance amplifier).

In the transmission case, the circuit operates as described above. The resonant circuit 204 may be tuned via the third terminal A3 and the fourth terminal A4 of the microcontroller 202 and may be excited to oscillate via the first terminal A1 and the sixth terminal A6. The operational amplifier OPV may be deactivated.

In the reception case, the operational amplifier OPV may be activated, and the third terminal A3 and the fourth terminal A4 may be switched to a fixed reference potential (e.g. ground). As long as the operational amplifier OPV does not overdrive, the voltage between its inputs equals zero, and the connection represents a virtual short circuit and the resonant circuit 204 oscillates in series resonance.

For the voltage between the two inputs 261 and 263 of the operational amplifier OPV to be equal to zero, regardless of the current I_{L} induced in the coil L1, the operational amplifier OPV controls the voltage at the second terminal A2 of the microcontroller 202 as follows:

$$\\ {U}_{pin 2} = - {I}_{L} * {R}_{gain} + {U}_{bias}$$

wherein U_{bias} the voltage, defined by the ratio of the resistors R2 and R3, at the input 263 of the operational amplifier OPV.

If the second terminal A2 and the fifth terminal A5 of the microcontroller 202 are comparator inputs, they may already read the received signal with a small amplification. If the first resistance R1 or R_{gain} is increased such that the operational amplifier OPV already overdrives at very small input signals, it is also possible to read the reception signal by means of a normal digital input.

The two MOSFETS 292 and 294 function to decrease the driver impedance in the transmission case and to drive more current through the coil L1.

The embodiment shown in FIG. 10 has the advantage that the signal read-in only depends on the current induced in the reception coil L1 and that the driver performance of the operational amplifier OPV efficiently suppresses prevalent external disturbances, deviations of the supply voltage and internal switching slopes on the board.

In embodiments, the serial resonant circuit is used for transmission and reception of signals.

In embodiments, the transmission/reception arrangement (or the circuit of the transmission/reception arrangement) is configured to measure the reception signal as a current flow in a series resonant circuit.

In embodiments, the signals may be received by any resonant circuit. With this circuit, it is also possible to transmit from a series to a parallel resonant circuit.

In embodiments, an amplifier with a low input resistance is used (Rᵢₙ<R_{coil}, e.g. transimpedance amplifier), as a result of which the use of a series resonant circuit (for receiving) becomes possible.

Embodiments of the transmission/reception arrangement described herein are less susceptible to capacitively coupled disturbances/interferences.

Embodiments of the transmission/reception arrangement (or the circuit of the transmission/reception arrangement) described herein enable a significantly higher reception signal in the voltage range than a comparable parallel resonant circuit would be able to generate.

Embodiments of the transmission/reception arrangement described therein have the advantage that the larger reception signal improves the sensitivity since internal comparators often have a comparably large offset.

In embodiments, the transmission signal is amplified by use of two MOSFETS.

In embodiments, comparators are not required if the amplification is sufficiently large.

In embodiments, transmission may be performed from a series resonant circuit to a parallel resonant circuit, and reception may be performed from a parallel resonant circuit to a series resonant circuit, or reception may be performed from a series resonant circuit with a series resonant circuit.

In embodiments, the comparator may be implemented so as to be internal or external. In embodiments, the comparator may also be omitted.

### 5. Further Embodiments

Embodiments of the present invention provide a cost-efficient and generally available concept to configure devices, above all sensor nodes, or to read them out and configure them in the context of service applications.

Embodiments specify a hardware configuration of the transmission/reception arrangement and enable a larger range and data rate for bidirectional communication with a resonant circuit and/or bidirectional communication via sound.

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described within the context of or as a method step also represent a description of a corresponding block or detail or feature of a corresponding device. Some or all of the method steps may be performed while using a hardware device, such as a microprocessor, a programmable computer, or an electronic circuit. In some embodiments, some or several of the most important method steps may be performed by such a device. Depending on specific implementation requirements, embodiments of the invention may be implemented in hardware or in software. Implementation may be effected while using a digital storage medium, for example a floppy disc, a DVD, a Blu-ray disc, a CD, a ROM, a PROM, an EPROM, an EEPROM or a FLASH memory, a hard disc or any other magnetic or optical memory which has electronically readable control signals stored thereon which may cooperate, or cooperate, with a programmable computer system such that the respective method is performed. This is why the digital storage medium may be computer-readable.

Some embodiments in accordance with the invention thus comprise a data carrier comprising electronically readable control signals that are capable of cooperating with a programmable computer system such that any of the methods described herein is performed.

Generally, embodiments of the present invention may be implemented as a computer program product having a program code, the program code being effective to perform any of the methods when the computer program product runs on a computer.

The program code may also be stored on a machine-readable carrier, for example.

Other embodiments include the computer program for performing any of the methods described herein, said computer program being stored on a machine-readable carrier.

In other words, an embodiment of the inventive method thus is a computer program which has a program code for performing any of the methods described herein, when the computer program runs on a computer.

A further embodiment of the inventive methods thus is a data carrier (or a digital storage medium or a computer-readable medium) on which the computer program for performing any of the methods described herein is recorded. The data carrier, the digital storage medium, or the recorded medium is typically tangible, or non-volatile.

A further embodiment of the inventive method thus is a data stream or a sequence of signals representing the computer program for performing any of the methods described herein. The data stream or the sequence of signals may be configured, for example, to be transmitted via a data communication link, for example via the internet.

A further embodiment includes a processing unit, for example a computer or a programmable logic device, configured or adapted to perform any of the methods described herein.

A further embodiment includes a computer on which the computer program for performing any of the methods described herein is installed.

A further embodiment in accordance with the invention includes a device or a system configured to transmit a computer program for performing at least one of the methods described herein to a receiver. The transmission may be electronic or optical, for example.

The receiver may be a computer, a mobile device, a memory device, or a similar device, for example. The device or the system may include a file server for transmitting the computer program to the receiver, for example.

In some embodiments, a programmable logic device (for example a field-programmable gate array, an FPGA) may be used for performing some or all of the functionalities of the methods described herein. In some embodiments, a field-programmable gate array may cooperate with a microprocessor to perform any of the methods described herein. Generally, the methods are performed, in some embodiments, by any hardware device. Said hardware device may be any universally applicable hardware such as a computer processor (CPU), or may be a hardware specific to the method, such as an ASIC.

For example, the apparatuses described herein may be implemented using a hardware device, or using a computer, or using a combination of a hardware device and a computer.

The apparatuses described herein, or any components of the apparatuses described herein, may at least be partially implement in hardware and/or software (computer program).

For example, the methods described herein may be implemented using a hardware device, or using a computer, or using a combination of a hardware device and a computer.

The methods described herein, or any components of the methods described herein, may at least be partially implement by performed and/or software (computer program).

The above-described embodiments merely represent an illustration of the principles of the present invention. It is understood that other persons skilled in the art will appreciate modifications and variations of the arrangements and details described herein. This is why it is intended that the invention be limited only by the scope of the following claims rather than by the specific details that have been presented herein by means of the description and the discussion of the embodiments.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### BIBLIOGRAPHY

[1] DE102018212957B3
[2] DE102018214716A1
[3] DE102019201152B3
[4] DE102019206848B3
[5] DE102019206836A1
[6] DE102019220227A1
[7] DE102020208155A1

1. Transmission/reception arrangement for transmission/reception of magnetic signals, wherein the transmission/reception arrangement comprises:
a microcontroller, and
an electromagnetic resonant circuit,
wherein the microcontroller is connected to the electromagnetic resonant circuit,
wherein the microcontroller is configured, in a transmission mode,
to operate the electromagnetic resonant circuit in series resonance, and
to generate a first signal for driving the electromagnetic resonant circuit, and to drive the electromagnetic resonant circuit with the generated first signal so as to generate, with the electromagnetic resonant circuit, a first magnetic signal carrying first data,
wherein the microcontroller is configured, in a reception mode,
to operate electromagnetic resonant circuit in series resonance, and
to evaluate a second signal provided by the electromagnetic resonant circuit, said second signal depending on a second magnetic signal detected by the electromagnetic resonant circuit, so as to receive second data.

2. Transmission/reception arrangement according to claim 1,
wherein the electromagnetic resonant circuit comprises a coil and a capacitor connected in series between a first node and second node,
wherein, in a transmission mode,
a first reference potential is applied at the second node, and
the microcontroller is configured to generate a first signal for driving the electromagnetic resonant circuit, and to apply the generated first signal to the electromagnetic resonant circuit via the first node so as to generate, with the electromagnetic resonant circuit, a first magnetic signal carrying first data,
wherein, in a reception mode,
a second reference potential is applied at the first or second node, and
to tap, via the first node or the second node, a second signal provided by the electromagnetic resonant circuit, said second signal depending on a second magnetic signal received by the electromagnetic resonant circuit, so as to acquire second data.

3. Transmission/reception arrangement according to claim 2,
wherein the microcontroller is connected to the electromagnetic resonant circuit via a reconfiguration circuit,
wherein the microcontroller is configured, in the transmission mode,
to generate a first signal for driving the electromagnetic resonant circuit, and to drive the electromagnetic resonant circuit with the generated first signal so as to generate, with the electromagnetic resonant circuit, a first magnetic signal carrying first data,
wherein the microcontroller is configured, in a reception mode,
to sense, via the reconfiguration circuit, a second signal provided by the electromagnetic resonant circuit, said second signal depending on a second magnetic signal received by the electromagnetic resonant circuit, so as to acquire second data,
wherein the reconfiguration circuit is configured to convert a current into an output voltage.

4. Transmission/reception arrangement according to claim 3,
wherein the reconfiguration circuit is a current-voltage converter or a low-impedance amplifier.

5. Transmission/reception arrangement according to claim 4,
wherein the low-impedance amplifier is a transimpedance amplifier or an operational amplifier connected as a transimpedance amplifier.

6. Transmission/reception arrangement according to claim 1,
wherein the electromagnetic resonant circuit comprises a coil and a capacitor connected in series between a first node and a second node,
wherein the coil and the capacitor are connected to each other via a third node.

7. Transmission/reception arrangement according to claim 6,
wherein the microcontroller is configured, in the transmission mode, to apply the first signal at the first node,
and/or wherein the microcontroller is configured, in the transmission mode, to apply a reference potential or a signal that is complementary to the first signal at the second node,
and/or wherein the microcontroller is configured, in the reception mode, to apply a reference potential at the second node.

8. Transmission/reception arrangement according to claim 7,
wherein the microcontroller is configured, in the transmission mode, to apply a reference potential or a signal that is complementary to the first signal at the second node.

9. Transmission/reception arrangement according to claim 6,
wherein the microcontroller is configured, in the reception mode, to apply a reference potential at the second node.

10. Transmission/reception arrangement according to claim 6,
wherein a first terminal of the microcontroller is connected to the first node,
wherein a second terminal of the microcontroller is connected to the first node via the operational amplifier connected as a transimpedance amplifier.

11. Transmission/reception arrangement according to claim 6,
wherein the second node is connected to a third terminal of the microcontroller or to a reference potential terminal.

12. Transmission/reception arrangement according to claim 6,
wherein the electromagnetic resonant circuit further comprises a tuning capacitor connected between the third node and a fourth terminal of the microcontroller,
wherein the microcontroller is configured to tune the electromagnetic resonant circuit by switching the fourth terminal to one of at least two different operation modes.

13. Transmission/reception arrangement according to claim 5,
wherein the operational amplifier connected as a transimpedance amplifier is connected as follows:
a first input of the operational amplifier is connected to the first node,
wherein a second input of the operational amplifier is connected to a reference potential terminal via a bypass capacitor,
wherein an output of the operational amplifier is connected to the second terminal of the microcontroller,
wherein a first resistor is connected in series between the first node and the second terminal of the microcontroller,
wherein a first diode is connected in the forward direction between the first node and the second terminal of the microcontroller,
wherein a second diode may be connected in the reverse direction between the first node and the second terminal of the microcontroller,
wherein a first supply terminal of the operational amplifier is connected to a supply voltage terminal,
wherein a second supply terminal of the operational amplifier is connected to a reference potential terminal,
wherein the first supply terminal is connected to the reference potential terminal via two resistors connected in series,
wherein a node between the two resistors connected in series is connected to the second input of the operational amplifier,
wherein the second terminal of a microcontroller is connected to a fifth terminal of the microcontroller via a fourth resistor,
wherein the fifth terminal of the microcontroller is connected to a reference potential terminal via a second capacitor.

14. Transmission/reception arrangement according to claim 13,
wherein the operational amplifier is configured, in the reception mode, to control a voltage Uₒᵤₜₚᵤₜ provided at the output, on the basis of the following equation:
$$\\ {U}_{output} = - {I}_{L} \cdot R 1 + {U}_{input 2}$$
wherein I_{L} is the current flowing through the coil of the electromagnetic resonant circuit wherein R1 is the resistance of the first resistor, and wherein U_{input 2} is a voltage at the second input of the operational amplifier.

15. Transmission/reception arrangement according to claim 13,
wherein the second terminal and the fifth terminal of the microcontroller are comparator inputs.

16. Transmission/reception arrangement according to claim 6,
wherein the first terminal of the microcontroller is connected to the first node,
or wherein the first terminal of the microcontroller is connected to the first node via an amplifier circuit.

17. Transmission/reception arrangement according to claim 16,
wherein the amplifier circuit comprises a first electronic switch and a second electronic switch connected in series between a supply voltage terminal and a reference potential terminal, wherein an output terminal of the amplifier circuit between the first electronic switch and the second electronic switch is connected to the first node,
wherein the microcontroller is configured, in the transmission mode, to apply, via the amplifier circuit, a pulse-width modulated first signal at the first node.

18. Device, comprising:
a configuration interface and/or operation interface for configuring and/or operating the device,
wherein the configuration interface and/or operation interface comprises a transmission/reception arrangement according to claim 1.
